(19) United States
(12) Patent Application Publication
(10) Pub. No.: US 2007/0072411 A1
(43) Pub. Date: Mar. 29, 2007

(54) Method for forming metal line in semiconductor device

(75) Inventors: Sang-Hoon Cho, Ichon-shi (KR); Ik-Soo Choi, Ichon-shi (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: HYNIX SEMICONDUCTOR INC.

(21) Appl. No.: 11/448,942

(22) Filed: Jun. 8, 2006

(30) Foreign Application Priority Data
Sep. 29, 2005 (KR) 10-2005-0091579

(51) Int. Cl. H01L 21/4763; H01L 21/20

(52) U.S. Cl. 438/637; 438/396

(57) ABSTRACT

A method for forming a metal line in a semiconductor device includes forming a plug buried in an inter-layer insulation layer formed over a substrate, forming a metal line layer over the plug and the substrate, forming a contact mask over the metal line layer, etching first portions of the metal line layer using the contact mask as an etch mask to form openings, forming a spacer layer over the metal line layer and the contact mask, and etching second portions of the metal line layer underneath the openings until portions of the inter-layer insulation layer are exposed to form spacers on sidewalls of the first portions of the metal line layer and the contact mask and to obtain isolated metal lines.

### RELATED APPLICATION

The present application is based on and claims the benefit of priority to Korean patent application No. KR 2005-91579, filed in the Korean Patent Office on Sep. 29, 2005, the entire contents of which are incorporated herein by reference.

### TECHNICAL FIELD

The present invention relates to a method for fabricating a semiconductor device, and more particularly, to a method for forming a metal line in a semiconductor device.

### DESCRIPTION OF RELATED ARTS

During a fabrication process of a dynamic random access memory (DRAM) having a multi-layered structure, the thickness of a photoresist layer has been generally required to be decreased during a photo mask process to define a line width of lines and spaces, as the design rule of metal lines has decreased.

FIGS. 1A and 1B illustrate cross-sectional views to describe a typical method for forming a metal line in a semiconductor device.

As shown in FIG. 1A, an inter-layer insulation layer 12 is formed on a substrate 11. The inter-layer insulation layer 12 is selectively etched to form a contact hole (not shown), and a conductive layer for forming a plug is filled into the contact hole to form a plug 13 contacting the substrate 11.

A first barrier metal layer 14 is formed on the inter-layer insulation layer 12. The first barrier metal layer 14 is formed in a stacked structure, including a titanium (Ti) layer 14A and a titanium nitride (TiN) layer 14B. A metal line layer 15 is formed on the first barrier metal layer 14. A second barrier metal layer 16 is formed on the metal line layer 15. The second barrier metal layer 16 is formed in a stacked structure, including another Ti layer 16A and another TiN layer 16B. An anti-reflective coating layer 17 is formed on the second barrier metal layer 16, and then, a photoresist pattern 18 is formed over a predetermined portion of the anti-reflective coating layer 17.

As shown in FIG. 1B, the anti-reflective coating layer 17, the second barrier metal layer 16, the metal line layer 15, and the first barrier metal layer 14 are etched, using the photoresist pattern 18 as an etch mask, to form contact holes 19 which expose portions of the inter-layer insulation layer 12. Reference numerals 14X, 15A, 16X, and 17A denote a patterned first barrier metal layer, a patterned metal line layer, a patterned second barrier metal layer, and a patterned anti-reflective coating layer, and reference numerals 14A1, 14B1, 16A1, and 16B1 denote a patterned Ti layer, a patterned TiN layer, another patterned Ti layer, and another patterned TiN layer. Particularly, the patterned metal line layer 15A will be referred to as the metal line.

Meanwhile, because an over etching process is performed to form the contact holes 19 using the photoresist pattern 18 as the etch mask, the photoresist pattern 18 is generally required to be relatively thick depending on the depth of the contact holes 19.

However, due to a lack of overlap margin between the photoresist pattern 18 and the plug 13 during the etching of the contact holes 19, a portion of the plug 13 is exposed as denoted with a reference denotation ‘A’, and thus, a short-circuit may occur between the plug 13 and metal lines to be formed in a subsequent process.

Also, a notch event may occur on sidewalls of the metal line layer 15A as a result of the over etching for forming the contact holes 19. The notch event is often generated because of weaknesses of a photo mask profile. When a metal is buried in the contact holes 19 and a chemical mechanical polishing (CMP) process is performed in a subsequent process, the notch event often generate a metal bridge.

Thus, a top portion damage is often generated in the metal line due to the lack of photoresist margin during the etching of the contact holes, and a failure, caused by the bridge between the metals due to the insufficient over etching, often occurs. Furthermore, because of the lack of overlap margin between the metal contact and the metal, chip contact etching has become more difficult.

Generally, a hard mask has been applied to overcome such limitation with respect to the lack of photoresist margin. However, this method generally requires caution in selecting a hard mask material, and the notch event occurring on the sidewalls of the metal due to the over etching is still difficult to control.

### SUMMARY

The present invention provides a method for forming a metal line in a semiconductor device, which may reduce a photoresist margin reduction and a bridge failure.

Consistent with the present invention, there is provided a method for forming a metal line in a semiconductor device, including: forming a plug buried in an inter-layer insulation layer formed over a substrate; forming a metal line layer over the plug and the substrate; forming a contact mask over the metal line layer; etching first portions of the metal line layer using the contact mask as an etch mask to form openings; forming a spacer layer over the metal line layer and the contact mask; and etching second portions of the metal line layer underneath the openings until portions of the inter-layer insulation layer are exposed to form spacers on sidewalls of the first portions of the metal line layer and the contact mask and to obtain isolated metal lines.

Additional features and advantages of the invention will be set forth in part in the description which follows, and in part will be apparent from that description, or may be learned by practice of the invention. The features and advantages of the invention will be realized and attained by means of the elements and combinations particularly pointed out in the appended claims.

It is to be understood that both the foregoing general description and the following detailed description are exemplary and explanatory and are intended to provide further explanation of the invention as claimed.

### BRIEF DESCRIPTION OF THE DRAWINGS

The above and other features of the present invention will become better understood with respect to the following description of the exemplary embodiments given in conjunction with the accompanying drawings, in which:

FIGS. 1A and 1B are cross-sectional views illustrating a typical method for forming a metal line in a semiconductor device; and

FIGS. 2A to 2E are cross-sectional views illustrating a method for forming a metal in a semiconductor device consistent with the present invention.

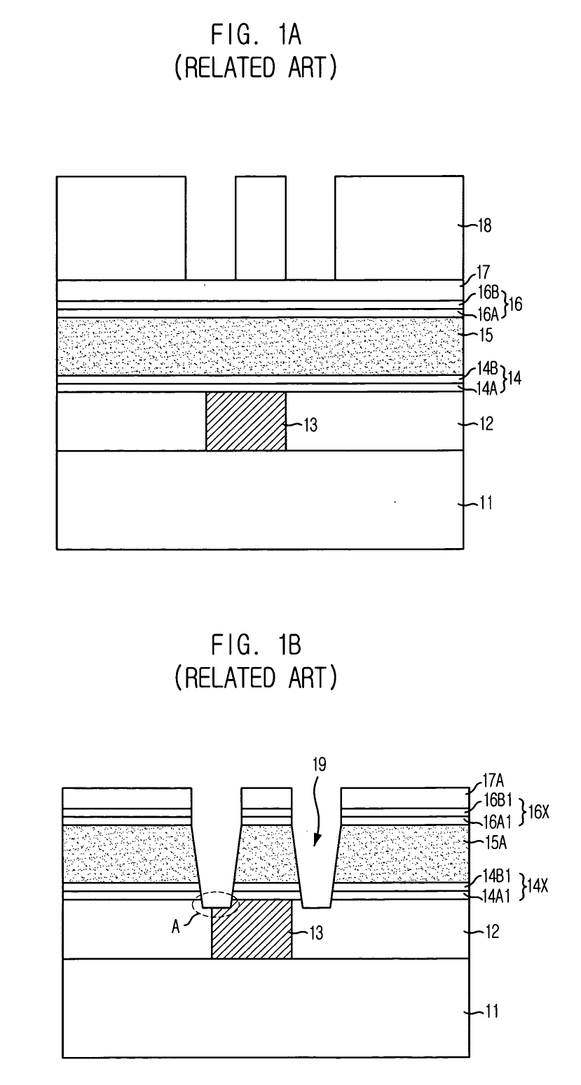

### DETAILED DESCRIPTION OF THE INVENTION

A method for forming a metal line in a semiconductor device in accordance with exemplary embodiments of the present invention will be described in detail with reference to the accompanying drawings.

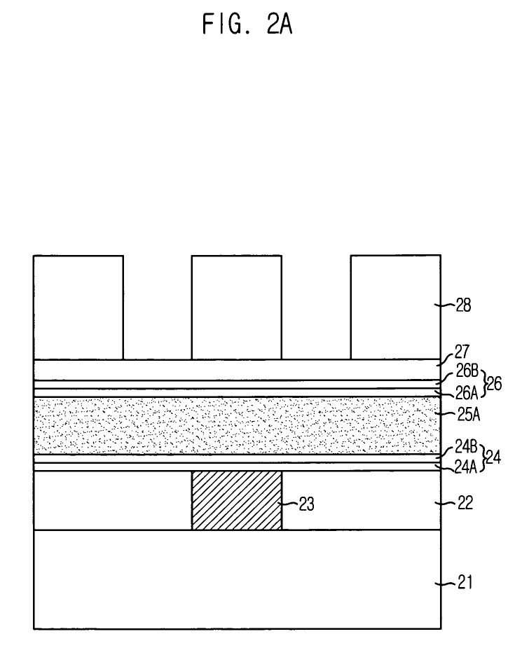

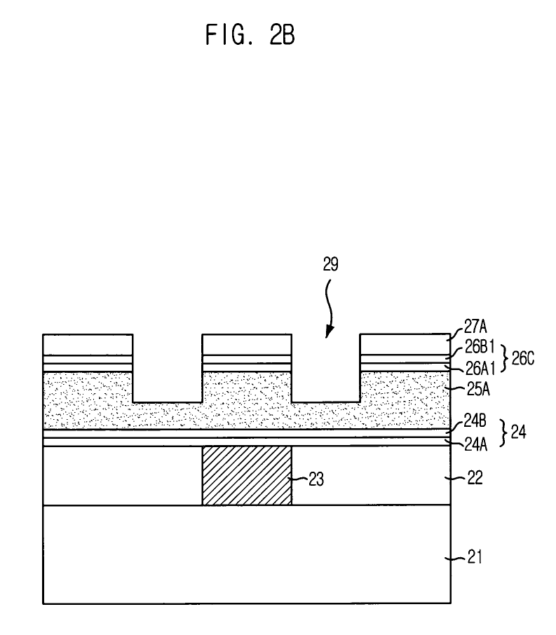

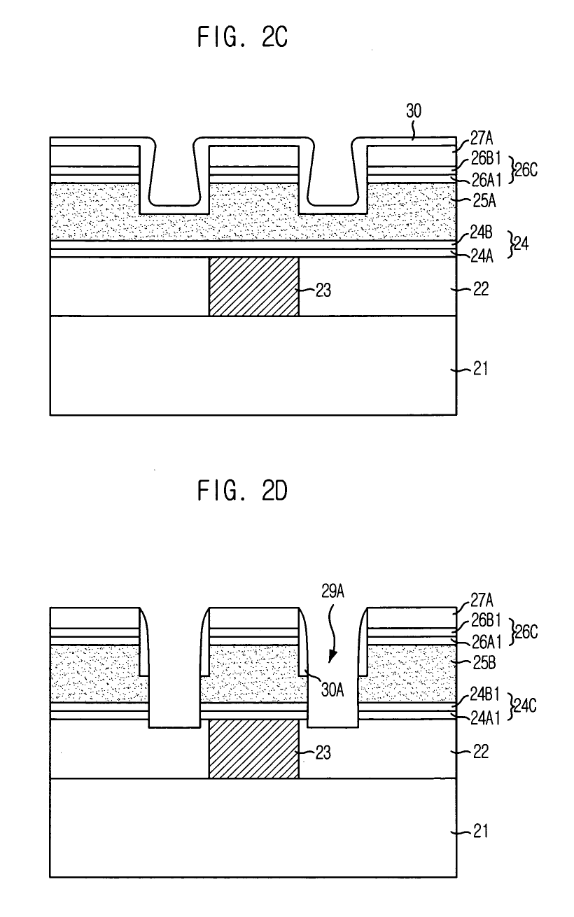

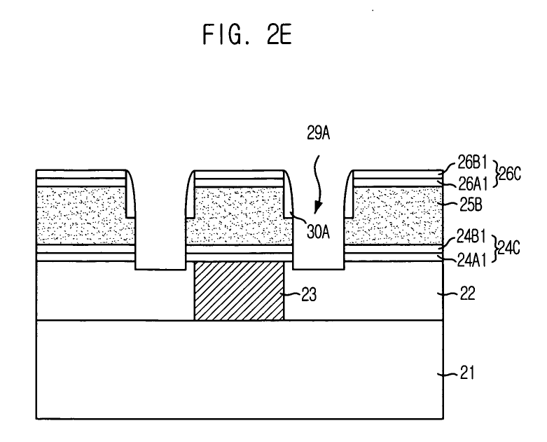

FIGS. 2A to 2E illustrate cross-sectional views to describe a method for forming a metal line in a semiconductor device consistent with the present invention.

As shown in FIG. 2A, an inter-layer insulation layer 22 is formed over a substrate 21. The inter-layer insulation layer 22 is selectively etched to form a contact hole (not shown), and a conductive layer for forming a plug is filled into the contact hole to form a plug 23 contacting the substrate 21. The plug 23 includes one of tungsten and polysilicon.

A first barrier metal layer 24 is formed over the inter-layer insulation layer 22. The first barrier metal layer 24 is formed in a stacked structure, including a titanium (Ti) layer 24A and a titanium nitride (TiN) layer 24B. A metal line layer 25 is formed over the first barrier metal layer 24. The metal line layer 25 includes one of aluminum (Al) and copper (Cu). A second barrier metal layer 26 is formed over the metal line layer 25. The second barrier metal layer 26 is formed in a stacked structure, including another Ti layer 26A and another TiN layer 26B. An anti-reflective coating layer 27 is formed over the second barrier metal layer 26, and then, a photoresist pattern 28 is formed over a predetermined portion of the anti-reflective coating layer 27. The anti-reflective coating layer 27 includes silicon oxynitride (SiON). The photoresist pattern 28 is used as an etch mask during a subsequent partial etching process. Thus, the photoresist pattern 28 is formed in a thickeness corresponding to the depth of an etch target portion subject to the partial etching process.

The inter-layer insulation layer 22 comprises one selected from a group consisting of a borosilicate glass (BSG) layer, a borophosphosilicate glass (BPSG) layer, a phosphosilicate glass (PSG) layer, a tetraethyle orthosilicate (TEOS) layer, a high density plasma (HDP) oxide layer, a spin on glass (SOG) layer, and an advanced planarization layer (APL). Also, instead of the oxide-based layers, the inter-layer insulation layer 22 may include an inorganic- or organic-based low-k dielectric layer.

As shown in FIG. 2B, the anti-reflective coating layer 27, the second barrier metal layer 26, and the metal line layer 25 are partially etched in sequential order, using the photoresist pattern 28 as an etch mask, to form openings 29. The partial etching process is performed until the above etch target thickness reaches up to approximately 30% to approximately 50% of the depth of the metal line layer 25. Reference numerals 25A, 26A1, 26B1, and 27A denote a patterned metal line layer, a patterned Ti layer, a patterned TiN layer, and a patterned anti-reflective coating layer, and particularly, reference numeral 26C refers to a patterned second barrier metal layer. The photoresist pattern 28 is stripped away, and a cleaning process is performed thereafter.

As shown in FIG. 2C, a spacer layer 30 is formed over the above resulting substrate structure illustrated in FIG. 2B. The spacer layer 30 includes a material having a poor step coverage characteristic, to utilize a non-uniform deposition characteristic of the material. That is, the spacer layer 30 is formed thicker on upper portions of the openings 29 than on side and bottom portions of the openings 29. Thus, the spacer layer 30 may comprise an undoped silicon glass (USG) layer.

As shown in FIG. 2D, a blanket dry etching process is performed to form contact holes 29A until predetermined portions of the inter-layer insulation layer 22 are exposed. The spacer layer 30 is also etched to thereby form spacers 30A on sidewalls of the patterned metal line layer 25A, the patterned second barrier metal layer 26C, and the patterned anti-reflective coating layer 27A patterned by the partial etching process. Reference numeral 25B denotes a metal isolated by the blanket dry etching process. The spacers 30A function as an etch barrier, and thus, while etching to form the contact holes 29A in the inter-layer insulation layer 22, a bridge failure can be reduced between the isolated metal lines 25B. Also, because the spacers 30A include an oxide-based material, the spacers 30A protect the sidewalls of the metal lines 25B, and thus, a notch event which may occur on the sidewalls thereof can be avoided. Meanwhile, since the blanket etching process does not require an etch mask, it is advantageous with respect to cost and process time reduction.

As shown in FIG. 2E, the patterned anti-reflective coating layer 27A is etched away after the contact holes 29A are formed, and the contact holes 29A are formed without defects from the etching process. By performing the partial etching process on the metal line to form the openings and then performing the entire contact hole etching, the thickness of the photoresist pattern can be reduced. Thus, short-circuits between the exposed plug and the metal line can be prevented by securing a larger margin between the photoresist pattern and the plug.

Consistent with the specific embodiment of the present invention, the reduction of the photoresist pattern margin for forming the metal line under 70 nm can be improved. Also, the occurrence of the bridge failure between adjacent metals can be reduced, and the overlap margin between metal contacts can be increased. Furthermore, the notch event generated by the over etching on the sidewalls of the metals can be reduced.

While the present invention has been described with respect to certain specific embodiments, it will be apparent to those skilled in the art that various changes and modifications may be made without departing from the spirit and scope of the invention as defined in the following claims.

What is claimed is:

1. A method for forming a metal line in a semiconductor device, the method comprising:
forming a plug buried in an inter-layer insulation layer formed over a substrate;
forming a metal line layer over the plug and the substrate;
forming a contact mask over the metal line layer;
etching first portions of the metal line layer using the contact mask as an etch mask to form openings;
forming a spacer layer over the metal line layer and the contact mask; and
etching second portions of the metal line layer underneath the openings until portions of the inter-layer insulation layer are exposed to form spacers on sidewalls of the first portions of the metal line layer and the contact mask and to obtain isolated metal lines.

2. The method of claim 1, wherein etching the first portions of the metal line layer-comprises etching the metal line layer up to approximately 30% to approximately 50% of the thickness thereof.

3. The method of claim 2, wherein the metal line layer includes one of aluminum and copper.

4. The method of claim 1, wherein forming the spacer layer comprises forming an undoped silicon glass (USG) layer.

5. The method of claim 1, wherein etching the second portions of the metal line layer comprises performing a blanket etching process.

6. The method of claim 5, wherein performing the blanket etching process includes performing a blanket dry etching.

7. The method of claim 1, further comprising:
forming a first barrier metal layer over the plug and the substrate, wherein forming the metal line layer comprises forming the metal line layer over the first barrier metal layer; and
forming a second barrier metal layer over the metal line layer.

8. The method of claim 7, wherein forming the first barrier metal layer comprises forming a stack structure including titanium (Ti) and titanium nitride (TiN), and forming the second barrier metal layer comprises forming a stack structure including Ti and TiN.

9. The method of claim 1, wherein forming the plug includes forming a plug comprising one of tungsten and polysilicon.

10. The method of claim 1, wherein forming the contact mask comprises:
forming an anti-reflective coating layer on the metal line layer; and
forming a photoresist pattern on the anti-reflective coating layer.

11. The method of claim 10, wherein forming the photoresist pattern comprises forming the photoresist pattern in a thickness corresponding to a depth of the openings.

12. The method of claim 10, further comprising:
removing the photoresist pattern after the etching of the first portions of the metal line layer; and
performing a cleaning process.

13. The method of claim 10, further comprising removing the anti-reflective coating layer after the etching of the second portions of the metal line layer underneath the openings.
